(19) United States
(12) Patent Application Publication
(10) Pub. No.: US 2025/0357229 A1
(43) Pub. Date: Nov. 20, 2025

(54) SEMICONDUCTOR PACKAGES INCLUDING SPACERS

(71) Applicant: Samsung Electronics Co., Ltd., Suwon-si (KR)

(72) Inventor: Hansae Lim, Suwon-si (KR)

(21) Appl. No.: 19/070,729

(22) Filed: Mar. 5, 2025

(30) Foreign Application Priority Data
May 16, 2024 (KR) 10-2024-0063880

(51) Int. Cl. H01L 23/24; H01L 23/00; H01L 23/31; H01L 23/498; H01L 25/18

(52) U.S. Cl. CPC H01L 23/24; H01L 23/3107; H01L 24/32; H01L 25/18; H01L 23/498; H01L 24/16; H01L 24/73; H01L 2224/16227; H01L 2224/32225; H01L 2224/73253

(57) ABSTRACT

A semiconductor package includes a semiconductor chip on a substrate, first and second spacers extending in a first horizontal direction on the semiconductor chip and spaced apart from each other in a second horizontal direction, and an encapsulant at least partially covering the substrate, the semiconductor chip, the first spacer, and the second spacer. An upper portion of the encapsulant is between the first and second spacers. First and second edge portions of the encapsulant overlap the semiconductor chip in the second horizontal direction and are spaced apart from each other in the second horizontal direction with the semiconductor chip interposed therebetween. An upper surface of the first spacer is coplanar with an upper surface of the upper portion of the encapsulant. The cross-sectional area of the upper portion of the encapsulant is equal to a sum of cross-sectional areas of the first and second edge portions of the encapsulant.

### CROSS-REFERENCE TO RELATED APPLICATION(S)

This application claims the benefit under 35 USC 119(a) of Korean Patent Application No. 10-2024-0063880, filed on May 16, 2024, in the Korean Intellectual Property Office, the entire disclosure of which is incorporated herein by reference for all purposes.

### FIELD OF THE INVENTION

The present inventive concept relates to semiconductor packages including spacers.

### BACKGROUND OF THE INVENTION

As demands for high performance, speed, and/or multifunctionality in semiconductor devices increase, the degree of integration of semiconductor devices is increasing. In manufacturing fine-patterned semiconductor devices in response to the trend for high integration of semiconductor devices, implementing patterns having a fine width or a fine spacing distance is required. Additionally, high integration of semiconductor devices mounted on semiconductor packages is required.

### SUMMARY

Example embodiments provide a semiconductor package including a spacer disposed on a semiconductor chip.

According to example embodiments, a semiconductor package may include a semiconductor chip on a substrate; a first spacer on the semiconductor chip and extending in a first horizontal direction; a second spacer on the semiconductor chip, extending in the first horizontal direction, and spaced apart from the first spacer in a second horizontal direction, wherein the second horizontal direction intersects the first horizontal direction; and an encapsulant at least partially covering the substrate, the semiconductor chip, the first spacer, and the second spacer. The encapsulant may include an upper portion, a first edge portion and a second edge portion. The upper portion of the encapsulant may be between the first spacer and the second spacer. The first edge portion and the second edge portion of the encapsulant overlap the semiconductor chip in the second horizontal direction and are spaced apart from each other in the second horizontal direction, with the semiconductor chip interposed between the first edge portion and the second edge portion of the encapsulant. An upper surface of the first spacer may be coplanar with an upper surface of the upper portion of the encapsulant. A cross-sectional area of the upper portion of the encapsulant may be substantially equal to a sum of a cross-sectional area of the first edge portion of the encapsulant and a cross-sectional area of the second edge portion of the encapsulant.

According to example embodiments, a semiconductor package may include a semiconductor chip on a substrate; a plurality of spacers on the semiconductor chip, extending in a first horizontal direction, and spaced apart from each other in a second horizontal direction, wherein the second horizontal direction intersects the first horizontal direction; and an encapsulant at least partially covering the substrate, the semiconductor chip, and the plurality of spacers. The encapsulant may include at least one upper portion, a first edge portion and a second edge portion. The at least one upper portion of the encapsulant may be between the plurality of spacers. The first edge portion and the second edge portion of the encapsulant overlap the semiconductor chip in the second horizontal direction and may be spaced apart from each other in the second horizontal direction with the semiconductor chip interposed between the first edge portion and the second edge portion of the encapsulant. Upper surfaces of the plurality of spacers may be coplanar with upper surface or surfaces of the at least one upper portion of the encapsulant. A cross-sectional area of the at least one upper portion of the encapsulant may be substantially equal to a sum of a cross-sectional area of the first edge portion of the encapsulant and a cross-sectional area of the second edge portion of the encapsulant.

According to example embodiments, a semiconductor package may include a substrate including an upper pad and an upper protective layer wherein the upper pad is exposed by the upper protective layer; a semiconductor chip on the substrate; a bump structure between the substrate and the semiconductor chip and electrically connected to the upper pad; a first spacer on the semiconductor chip and extending in a first horizontal direction; a second spacer on the semiconductor chip, extending in the first horizontal direction, and spaced apart from the first spacer in a second horizontal direction, wherein the second horizontal direction intersects the first horizontal direction; a first adhesive layer between the semiconductor chip and the first spacer; a second adhesive layer between the semiconductor chip and the second spacer; and an encapsulant at least partially covering the substrate, the semiconductor chip, the bump structure, the first spacer, and the second spacer. The encapsulant may include an upper portion, a first edge portion and a second edge portion. The upper portion of the encapsulant may be between the first spacer and the second spacer. The first edge portion and the second edge portion of the encapsulant overlap the upper protective layer in a vertical direction perpendicular to the first and second horizontal directions and may be spaced apart from each other in the second horizontal direction with the semiconductor chip interposed between the first edge portion and the second edge portion of the encapsulant. An upper surface of the first spacer may be coplanar with an upper surface of the upper portion of the encapsulant. A cross-sectional area of the upper portion of the encapsulant may be substantially equal to a sum of a cross-sectional area of the first edge portion of the encapsulant and a cross-sectional area of the second edge portion of the encapsulant.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a fragmentary, top plan view of a semiconductor package according to example embodiments;

FIG. 2A is a vertical cross-sectional view along line I-I′ of the semiconductor package illustrated in FIG. 1;

FIG. 2B shows enlarged views of portions R1 and R2 of the semiconductor package illustrated in FIG. 2A;

FIGS. 3 to 7 are fragmentary, top plan views of semiconductor packages according to example embodiments;

FIG. 8 is a fragmentary, top plan view of a semiconductor package according to example embodiments;

FIG. 9 is a vertical cross-sectional view taken along line II-II′ of the semiconductor package illustrated in FIG. 8;

FIG. 10 is a fragmentary, top plan view of a semiconductor package according to example embodiments;

FIG. 11 is a fragmentary, top plan view of a semiconductor package according to example embodiments;

FIG. 12 is a vertical cross-sectional view taken along line III-III′ of the semiconductor package illustrated in FIG. 11;

FIG. 13 is a fragmentary, top plan view of a semiconductor package according to example embodiments;

FIG. 14 is a fragmentary, top plan view of a semiconductor package according to example embodiments;

FIG. 15A is a vertical cross-sectional view taken along line IV-IV′ of the semiconductor package illustrated in FIG. 14;

FIG. 15B is an enlarged view of a portion R3 of the semiconductor package illustrated in FIG. 15A;

FIG. 16 is a fragmentary, top plan view of a semiconductor package according to example embodiments;

FIG. 17 is a fragmentary, top plan view of a semiconductor package according to example embodiments;

FIG. 18 is a vertical cross-sectional view taken along line V-V′ of the semiconductor package illustrated in FIG. 17;

FIG. 19 is a fragmentary, top plan view of a semiconductor package according to example embodiments;

FIGS. 20 to 22 are diagrams illustrating a molding process according to example embodiments;

FIG. 23 is a plan view illustrating a molding process according to a comparative example; and

FIGS. 24 and 25 are diagrams illustrating a molding process according to example embodiments.

### DETAILED DESCRIPTION

The above and other aspects and features of the semiconductor package and the methods of manufacturing the same in accordance with example embodiments will become readily understood from the detailed descriptions that follow, with reference to the accompanying drawings.

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process.

The terms “comprises,” “comprising,” “includes” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

A first element described as “on” a second element may be disposed directly on the second element (e.g., in contact with the second element) or indirectly on the second element (e.g., with an intervening element interposed between the first and second elements). When components or layers are referred to herein as “directly” on, or “in direct contact” or “directly connected,” no intervening components or layers are present.

The terms “surround” or “cover” or “fill” as may be used herein may not require completely surrounding or covering or filling the described elements or layers, but may, for example, refer to partially surrounding or covering or filling the described elements or layers, for example, with one or more discontinuities therein.

A first element that “covers” a second element may or may not be in contact with the second element.

Components or layers described with reference to “overlap” in a particular direction are at least partially obstructed by one another when viewed along a line extending in the particular direction or in a plane perpendicular to the particular direction. As used herein, “an element A overlapping an element B in a direction C” (or similar language) means that there is at least one line that extends in the direction C that intersects both the element A and the element B. For example, the element B may be a layer that is stacked or superimposed over (i.e., on top of) the element A, in which case the layer B may be described as overlapping the element A in a vertical direction. However, it will be appreciated that the direction C is not limited to the vertical direction and may be, for example, a horizontal direction or any direction between vertical and horizontal.

The term “exposed” may be used to describe relationships between elements and/or certain intermediate processes in fabricating a completed semiconductor device but may not necessarily require exposure of the particular region, layer, structure or other element in the context of the completed device. An “element A is exposed by an element B” means that at least a portion of the element A is not covered by the element B. However, the thus exposed portion of the element A may be covered by a third element.

For the purpose of explanation, certain dimensions of components are described herein as a component's “width” and the component's “length”. Unless otherwise specified, the use of these terms is not intended to mean that the width of the component is necessarily less than its length.

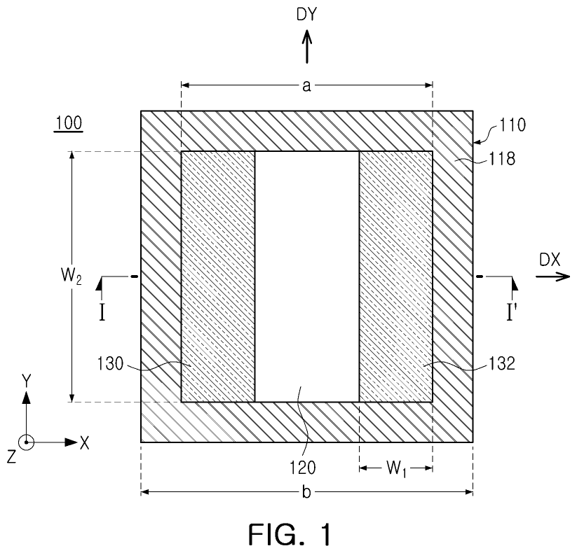

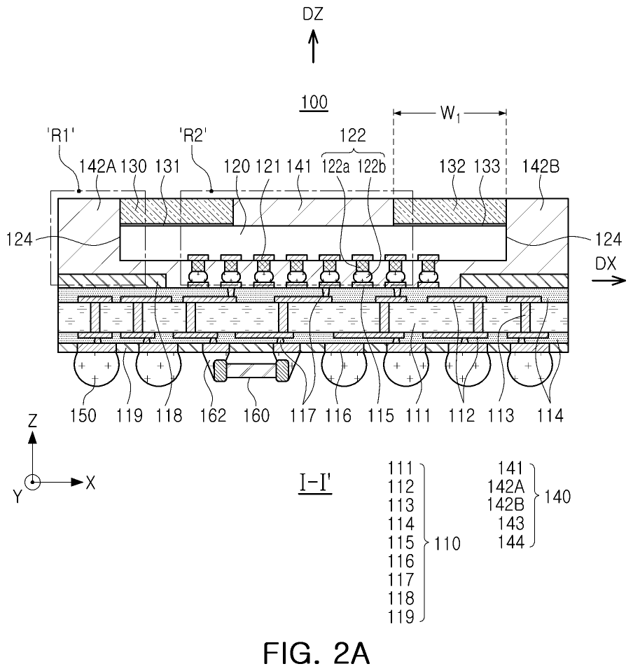

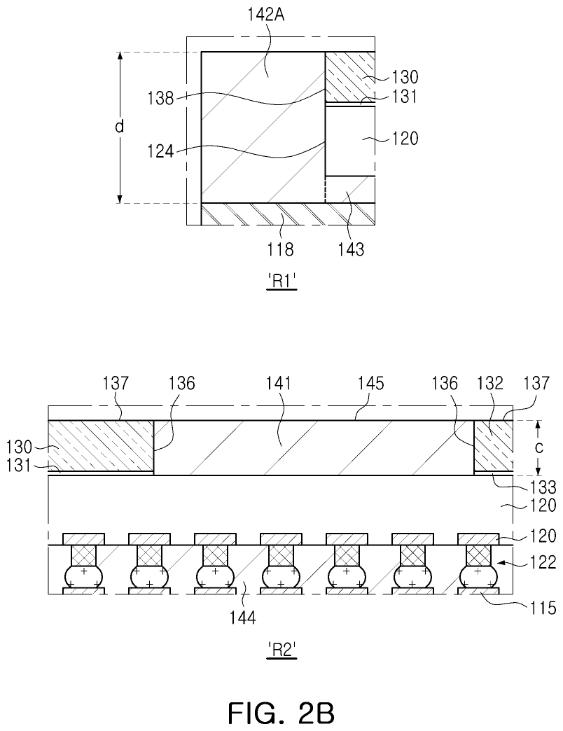

FIG. 1 is a fragmentary, plan view of a semiconductor package 100 according to example embodiments. FIG. 2A is a vertical cross-sectional view taken along line I-I′ of the semiconductor package 100 illustrated in FIG. 1. FIG. 2B shows enlarged views of regions R1 and R2 of the semiconductor package 100 as illustrated in FIG. 2A.

With reference to FIGS. 1 and 2A, the semiconductor package 100 defines an X-axis, a Y-axis and a Z-axis, as indicated in the figures. The X, Y and Z axes are each perpendicular to one another. The Y-axis may be referred to as a first horizontal axis, the X-axis may be referred to as a second horizontal axis, and the Z-axis may be referred to as a vertical axis.

Referring to FIGS. 1 to 2B, a semiconductor package 100 according to an example embodiment may include a substrate 110, a semiconductor chip 120, a first spacer 130, a second spacer 132, an encapsulant 140, and an external connection terminal 150. FIG. 1 is a fragmentary view in that the encapsulant 140 is not shown in FIG. 1, for the purpose of explanation.

The substrate 110 may include an insulating layer 111, an interconnection layer 112, a via 113, a protective layer 114, an upper pad 115, a lower pad 116, a via 117, an upper protective layer 118, and a lower protective layer 119. In an example embodiment, the substrate 110 may be a substrate for a semiconductor package, such as a printed circuit board (PCB), an interposer substrate, a ceramic substrate, or a tape interconnection board. In an example embodiment, the substrate 110 may be a printed circuit board. For example, the insulating layer 111 of the substrate 110 may include a thermosetting resin such as epoxy resin, a thermoplastic resin such as polyimide, or a photosensitive insulating layer, and in detail, may include materials such as prepreg, Ajinomoto Build-up Film (ABF), FR-4, Bismaleimide Triazine (BT), and Photoimageable Dielectric resin (PID). The insulating layer 111 may be formed using, for example, a copper clad laminate (CCL), an unclad copper clad laminate (CCL), a glass substrate, or a ceramic substrate. Depending on some example embodiments, the substrate 110 may not include the core insulating layer 111.

The interconnection layers 112 may be disposed on the lower and upper surfaces of the insulating layer 111. The vias 113 may extend vertically through the insulating layer 111. The interconnection layers 112 may be electrically connected to each other through the via 113. The interconnection layer 112 may include a metal material containing, for example, copper (Cu), aluminum (Al), silver (Ag), tin (Sn), gold (Au), nickel (Ni), lead (Pb), titanium (Ti), or alloys thereof. The lower interconnection layer 112 may include, for example, a ground pattern, a power pattern, and a signal pattern. The signal(S) pattern may provide a path through which various signals, for example, data signals, etc. are transmitted/received.

The via 113 is electrically connected to the interconnection layer 112 and may include a signal via, a ground via, and a power via. The via 113 may contain a metal material containing, for example, copper (Cu), aluminum (Al), silver (Ag), tin (Sn), gold (Au), nickel (Ni), lead (Pb), titanium (Ti), or alloys thereof. The via 113 may have the form of a filled via in which the inside of the via hole is filled with a metal material or a conformal via in which a metal material is formed along the inner wall of the via hole. The via 113 may be integrated with the interconnection layer 112, but example embodiments are not limited thereto.

The protective layer 114 may be disposed on the lower and upper surfaces of the insulating layer 111 and may cover the interconnection layers 112. The upper pad 115 and lower pad 116 may be disposed on the upper and lower surfaces of the substrate 110, respectively. The upper pad 115 and lower pad 116 may respectively be disposed on the protective layer 114. The upper pad 115 and lower pad 116 may be electrically connected to the corresponding interconnection layer 112 through vias 117. The upper pad 115, the lower pad 116, and the via 117 may contain a metal material that contains copper (Cu), aluminum (Al), silver (Ag), tin (Sn), gold (Au), nickel (Ni), lead (Pb), titanium (Ti), or alloys thereof.

The upper protective layer 118 and lower protective layer 119 may be disposed on the lower and upper surfaces of the substrate 110, respectively, and may cover the protective layer 114. The upper protective layer 118 may partially cover the protective layer 114. For example, the upper protective layer 118 may not cover the upper pads 115, and the upper pads 115 may be exposed by the upper protective layer 118. In an example embodiment, the side surfaces of upper pads 115 may be covered by the upper protective layer 118. The lower protective layer 119 may cover the side surfaces of the lower pads 116, and the lower surfaces of the lower pads 116 may be exposed by the lower protective layer 119.

The protective layer 114, the upper protective layer 118, and the lower protective layer 119 may include an insulating resin and an inorganic filler. For example, the protective layer 114, the upper protective layer 118, and the lower protective layer 119 may include ABF, but are not limited thereto. The protective layer 114, the upper protective layer 118, and the lower protective layer 119 may include a photoimageable dielectric (PID) material or an insulating polymer, for example, photosensitive polyimide (PSPI).

The semiconductor package 100 may further include a bump structure 122 disposed between the substrate 110 and the semiconductor chip 120. The semiconductor chip 120 may be placed on the substrate 110 and may be electrically connected to the substrate 110 by the bump structure 122. For example, the semiconductor chip 120 may include a chip pad 121 connected to the bump structure 122. The chip pad 121 may be disposed on the lower surface of the semiconductor chip 120 and may be in contact with the corresponding bump structure 122. For example, the bump structure 122 may have a flip-chip connection structure with solder balls, conductive bumps or a grid array such as a pin grid array, a ball grid array, or a land grid array.

The bump structures 122 may include a first part 122a contacting the chip pads 121 and a second part 122b connecting the first part 122a and the upper pad 115. For example, the first part 122a may be a metal post part, and the second part 122b may be a solder part containing a low melting point metal, but the present inventive concept is not limited thereto. Depending on some example embodiments, the bump structures 122 may include only the second portion 122b. The low melting point metal may include tin (Sn), indium (In), bismuth (Bi), antimony (Sb), copper (Cu), silver (Ag), zinc (Zn), lead (Pb) or alloys thereof (for example, Sn—Ag—Cu).

The semiconductor chip 120 may be a logic chip or a memory chip. The logic chip may include a microprocessor, analog element, or digital signal processor. The memory chip may include a volatile memory chip, such as Dynamic Random Access Memory (DRAM) or Static Random Access Memory (SRAM), or a bon-volatile memory chip, such as Phase-change Random Access Memory (PRAM), Magnetoresistive Random Access Memory (MRAM), Ferroelectric Random Access Memory (FeRAM), or Resistive Random Access Memory (RRAM).

In an example embodiment, at least one spacer 130 or 132 may be disposed on the semiconductor chip 120. In an example embodiment, a first spacer 130 and a second spacer 132 may be disposed on a semiconductor chip. The first spacer 130 and the second spacer 132 may extend in a Y-direction DY (which may be referred to herein as a first horizontal direction) and may be spaced apart from each other in an X-direction DX (which may be referred to herein as a second horizontal direction). The Y-direction DY and the X-direction DX are perpendicular to a Z-direction DZ (which may be referred to herein as a vertical direction). The Y-direction DY is parallel to the Y-axis. The X-direction DX is parallel to the X-axis. The Z-direction DZ is parallel to the Z-axis. At least one of the side surfaces of the semiconductor chip 120 may be coplanar with the first spacer 130 and the second spacer 132. For example, side surfaces perpendicular to the X-direction DX of the semiconductor chip 120 may be coplanar with the first spacer 130 and the second spacer 132, respectively. Side surfaces perpendicular to the Y-direction DY of the semiconductor chip 120 may be coplanar with the first spacer 130 and the second spacer 132, respectively. The length W₂ (FIG. 1) of the first spacer 130 and the second spacer 132 in the Y-direction DY may be substantially equal to the length of the semiconductor chip 120 in the Y-direction DY. The first spacer 130 and the second spacer 132 may have the same size.

In an example embodiment, the semiconductor package 100 may further include a first adhesive layer 131 disposed between the semiconductor chip 120 and the first spacer 130 and a second adhesive layer 133 disposed between the semiconductor chip 120 and the second spacer 132 (FIGS. 2A and 2B). The first adhesive layer 131 and the second adhesive layer 133 may attach the first spacer 130 and the second spacer 132 to the semiconductor chip 120, respectively. The first adhesive layer 131 and the second adhesive layer 133 may be die attach film (DAF). In some embodiments, the first adhesive layer 131 and the second adhesive layer 133 may be omitted, and the first spacer 130 and the second spacer 132 may be in direct contact with the upper surface of the semiconductor chip 120.

The encapsulant 140 may cover the substrate 110, the semiconductor chip 120, the first spacer 130, and the second spacer 132. For example, the encapsulant 140 may cover the upper surface of the substrate 110, and the semiconductor chip 120 may be buried in the encapsulant 140 and not exposed. Side surfaces of the first spacer 130 and the second spacer 132 may be covered with an encapsulant 140. The upper surfaces of the first spacer 130 and the second spacer 132 may not be covered by the encapsulant 140 and may be exposed. For example, the upper surfaces of the first spacer 130 and the second spacer 132 may be coplanar with the upper surface of the encapsulant 140.

The encapsulant 140 may include an upper portion 141, edge portions 142A, 142B, a first lower portion 143, and a second lower portion 144.

In some embodiments, the encapsulant 140 is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 1.

The upper portion 141 of the encapsulant 140 is disposed on the semiconductor chip 120 and at least partially overlaps the semiconductor chip 120 in the vertical direction DZ (Z-direction). The edge portions 142A, 142B of the encapsulant 140 are disposed on respective side surfaces 124 (FIG. 2B) of the semiconductor chip 120, and at least a portion of each edge portion 142A, 142B overlaps the semiconductor chip 120 in the X-direction DX, as shown in FIGS. 2A and 2B. For example, in the embodiment of FIGS. 1-2B, the upper portion 141 is disposed between the first spacer 130 and the second spacer 132, and is disposed on the semiconductor chip 120. The upper portion 141 may contact the inner side surfaces 136 of the first spacer 130 and the second spacer 132, and the upper surface 145 of the upper portion 141 may be coplanar with the upper surfaces 137 of the first spacer 130 and the second spacer 132. The upper portion 141 may contact the upper surface 125 (FIG. 2B) of the semiconductor chip 120.

The edge portions 142A, 142B are disposed on the upper protective layer 118 of the substrate 110 and may be disposed on both sides of the semiconductor chip 120. For example, the edge portions 142A, 142B may be spaced apart from each other in the X-direction DX with the semiconductor chip 120 interposed therebetween. Each of the edge portions 142A, 142B may contact a side surface 124 of the semiconductor chip 120 and may contact a corresponding outer side surface 138 of the first spacer 130 or the second spacer 132. Upper surfaces of the edge portions 142A, 142B may be coplanar with the upper surfaces 137 of the first spacer 130 and the second spacer 132. The upper portion 141 and the edge portions 142A, 142B may extend in the Y-direction DY along the first spacer 130 and the second spacer 132.

The first lower portion 143 of the encapsulant 140 is disposed between the upper protective layer 118 of the substrate 110 and the semiconductor chip 120. The lower surface of the first lower portion 143 may be coplanar with the lower surface of the edge portions 142A, 142B.

The second lower portion 144 of the encapsulant 140 is disposed between the substrate 110 and the semiconductor chip 120 and covers the bump structures 122. The second lower portion 144 may be disposed at a position corresponding to the center of the semiconductor chip 120, and the lower surface of the second lower portion 144 may be disposed on a level lower than that of the lower surfaces of the edge portions 142A, 142B and the first lower portion 143. The second lower portion 144 may be in contact with the side surface of the upper protective layer 118 and the upper surface of the protective layer 114.

The encapsulant 140 may be a resin containing epoxy or polyimide. For example, the resin may include bisphenol-group epoxy resin, polycyclic aromatic epoxy resin, o-cresol novolac epoxy resin, biphenyl-group epoxy resin, or naphthalene-group epoxy resin.

In an example embodiment, the first spacer 130 and the second spacer 132 may include a material with higher thermal conductivity than the encapsulant 140. For example, the first spacer 130 and the second spacer 132 may include silicon. The first spacer 130 and the second spacer 132 include a material with relatively high thermal conductivity, and since the upper surfaces are exposed by the encapsulant 140, heat generated from the semiconductor chip 120 may be effectively dissipated to the outside.

In an example embodiment, the width W₁ (FIG. 1) of the first spacer 130 and the second spacer 132 in the X-direction DX may respectively satisfy Equation 1 below.

$${W}_{1} = \frac{a}{2} - \frac{d ( b - a )}{2 c} \qquad [ Equation 1 ]$$

In this case, a is the width of the semiconductor chip 120 in the X-direction DX, b is the width of the substrate 110 in the X-direction DX, c (FIG. 2B) is the thickness (in the vertical direction DZ) of the upper portion 141 of the encapsulant 140, and d (FIG. 2B) is the thickness (in the vertical direction DZ) of each of the edge portions 142A, 142B of the encapsulant 140.

According to Equation 1, the cross-sectional area (in the X-Z plane) of the upper portion 141 of the encapsulant 140 may be substantially equal to the sum of the cross-sectional areas (in the X-Z plane) of the edge portions 142A, 142B of the encapsulant 140. For example, the first edge portion 142A and the second edge portion 142B may be spaced apart from each other in the X-direction DX with the semiconductor chip 120 interposed therebetween, and the sum of the cross-sectional areas of the first edge portion 142A and the second edge portion 142B may be equal to the cross-sectional area of the upper portion 141 of the encapsulant 140. In this case, the cross-sectional area may mean the area of the surface perpendicular to the Y-direction DY as viewed from the X-Z plane.

The external connection terminal 150 may be disposed on the lower surface of the substrate 110. The external connection terminal 150 may be in contact with the lower pad 116 disposed on the lower surface of the substrate 110. A ground voltage (Vss) or a power voltage (Vdd) may be applied to the lower pad 116. The external connection terminal 150 may be electrically connected to an external device such as a main board. The external connection terminal 150 may include a conductive material and may have a ball, pin, or lead shape. For example, the external connection terminal 150 may be a solder ball.

The semiconductor package 100 may further include a passive element 160 and a connection terminal 162 disposed below the substrate 110. The passive element 160 may be electrically connected to a corresponding one of the lower pads 116 through the connection terminal 162. The passive element 160 may include, for example, a capacitor such as a Multi-Layer Ceramic Capacitor (MLCC) or a Low Inductance Chip Capacitor (LICC), an inductor, beads, etc. In an example embodiment, the passive element 160 may be a Land-Side Capacitor (LSC). However, the present inventive concept is not limited thereto, and depending on some example embodiments, the passive element 160 may be a Die-Side Capacitor (DSC) mounted on the upper surface of the substrate 110, or an embedded type capacitor built into the interior of the substrate 110.

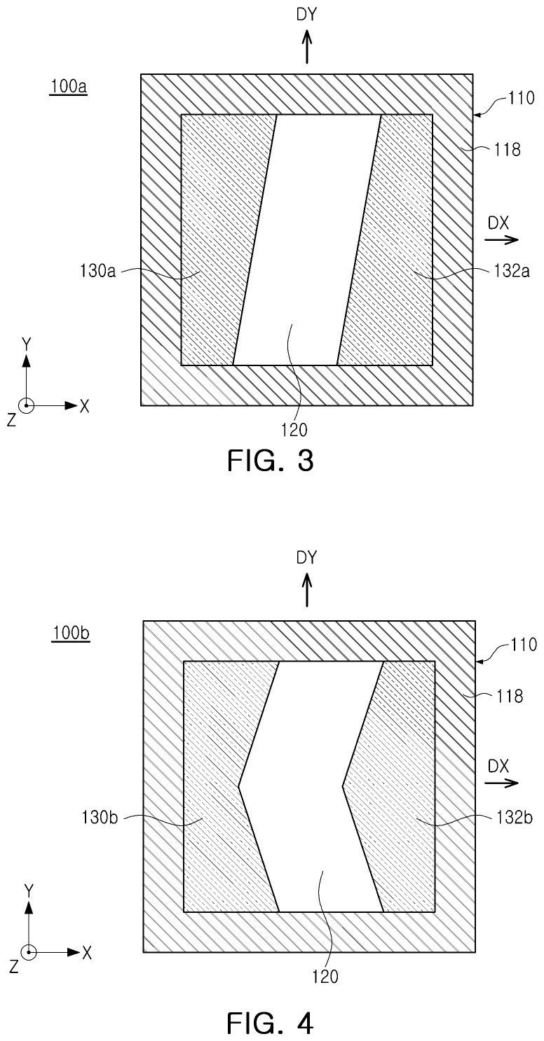

The semiconductor packages of FIGS. 3-19 may have structures substantially the same as those of the semiconductor package 100, except as discussed below. Therefore, repeated explanations of the same or similar elements and relationships are omitted below. FIGS. 3-8, 10, 11, 13, 14, 16, 17 and 19 are each fragmentary views in that, for the purpose of explanation, the encapsulant 140 is not shown in those figures. The placement of the encapsulant 140 (including the corresponding upper portion 141 and first and second edge portions 142A, 142B of the encapsulant) in each of the semiconductor packages 100a, 100b, 100c, 100d, 100e, 100f, 100g, 100h, 100i, 100j, 100k, 100l, 100m will be appreciated from the discussion herein and the figures.

FIGS. 3 to 7 are fragmentary, plan views of semiconductor packages according to example embodiments.

Referring to FIG. 3, a semiconductor package 100a may include a first spacer 130a and a second spacer 132a disposed on the semiconductor chip 120. In an example embodiment, the horizontal widths of the first spacer 130a and the second spacer 132a in the X-direction DX may vary in the Y-direction DY. For example, the horizontal widths of the first spacer 130a and the second spacer 132a in the X-direction may gradually decrease or increase in the Y-direction, respectively. The distance in the X-direction between the first spacer 130a and the second spacer 132a may be constant. The upper portion 141 of the encapsulant 140 described with reference to FIG. 2A may extend in the Y-direction between the first spacer 130a and the second spacer 132a. The horizontal width of the upper portion 141 of the encapsulant 140 in the X-direction may be constant. In some embodiments, the encapsulant 140 (not shown in FIG. 3) of the semiconductor package 100a is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 3.

Referring to FIG. 4, a semiconductor package 100b may include a first spacer 130b and a second spacer 132b disposed on the semiconductor chip 120. In an example embodiment, the horizontal widths of the first spacer 130b and the second spacer 132b in the X-direction may vary in the Y-direction. For example, the horizontal widths of the first spacer 130b and the second spacer 132b in the X-direction may gradually decrease and then increase in the Y-direction, or vice versa. The horizontal width of the upper portion 141 of the encapsulant 140 in the X-direction, described with reference to FIG. 2A, may be constant. In some embodiments, the encapsulant 140 (not shown in FIG. 4) of the semiconductor package 100b is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 4.

Referring to FIG. 5, a semiconductor package 100c may include a first spacer 130c and a second spacer 132c disposed on the semiconductor chip 120. In an example embodiment, the horizontal widths of the first spacer 130c and the second spacer 132c in the X-direction DX may vary in the Y-direction DY. For example, in a top view, the first spacer 130c and the second spacer 132c may include a concave portion, and the side surfaces of the first spacer 130c and the second spacer 132c facing each other may have a concave curved surface. In some embodiments, the encapsulant 140 (not shown in FIG. 5) of the semiconductor package 100c is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 5.

Referring to FIG. 6, a semiconductor package 100d may include a first spacer 130d and a second spacer 132d disposed on the semiconductor chip 120. In an example embodiment, the horizontal widths of the first spacer 130d and the second spacer 132d in the X-direction DX may vary in the Y-direction DY. For example, in a top view, the first spacer 130c and the second spacer 132c may include two or more concave portions.

Even in the embodiment of FIG. 5, the first spacer 130c and the second spacer 132c may have a width W₁ in the X-direction DX that satisfies Equation 1, and even in the embodiment of FIG. 6, the first spacer 130d and the second spacer 132d may have a width W₁ in the X-direction that satisfies Equation 1. In some embodiments, the encapsulant 140 (not shown in FIG. 6) of the semiconductor package 100d is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 6.

Referring to FIG. 7, a semiconductor package 100e may include a first spacer 130e and a second spacer 132e disposed on the semiconductor chip 120. In an example embodiment, the first spacer 130e and the second spacer 132e may extend in the Y-direction DY, and the length W₂ of the first spacer 130e and the second spacer 132e in the Y-direction may be greater than the length of the semiconductor chip 120 in the Y-direction. For example, the length W₂ may be substantially equal to the length of the substrate 110 in the Y-direction. The side surfaces 139 of the first spacer 130e and the second spacer 132e perpendicular to the Y-direction may be coplanar with the side surface of the substrate 110 and may be exposed without being covered by the encapsulant 140. Since not only the upper surfaces but also the side surfaces of the first spacer 130e and the second spacer 132e are exposed by the encapsulant 140, heat generated in the semiconductor chip 120 may be effectively dissipated to the outside. In some embodiments, the encapsulant 140 (not shown in FIG. 7) of the semiconductor package 100e is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 7.

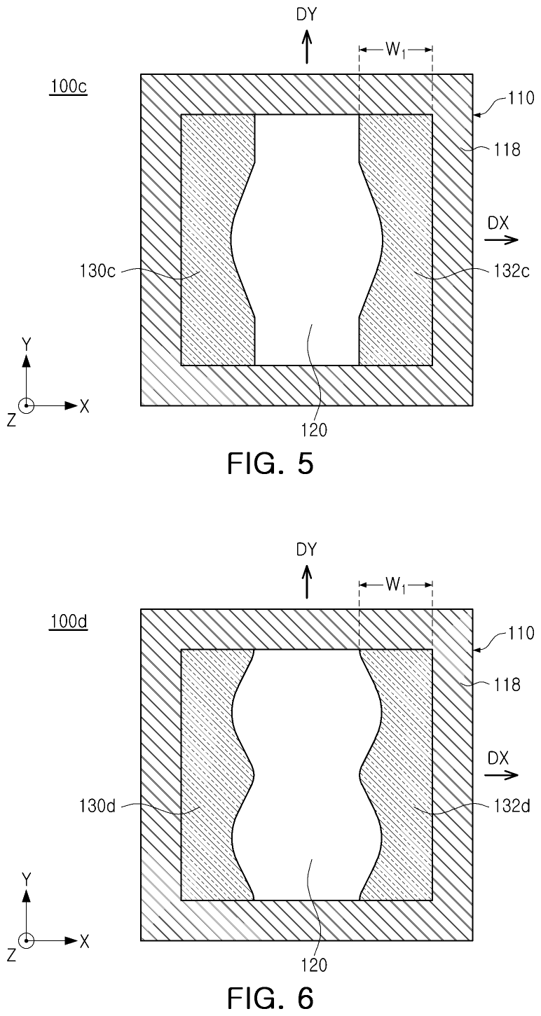

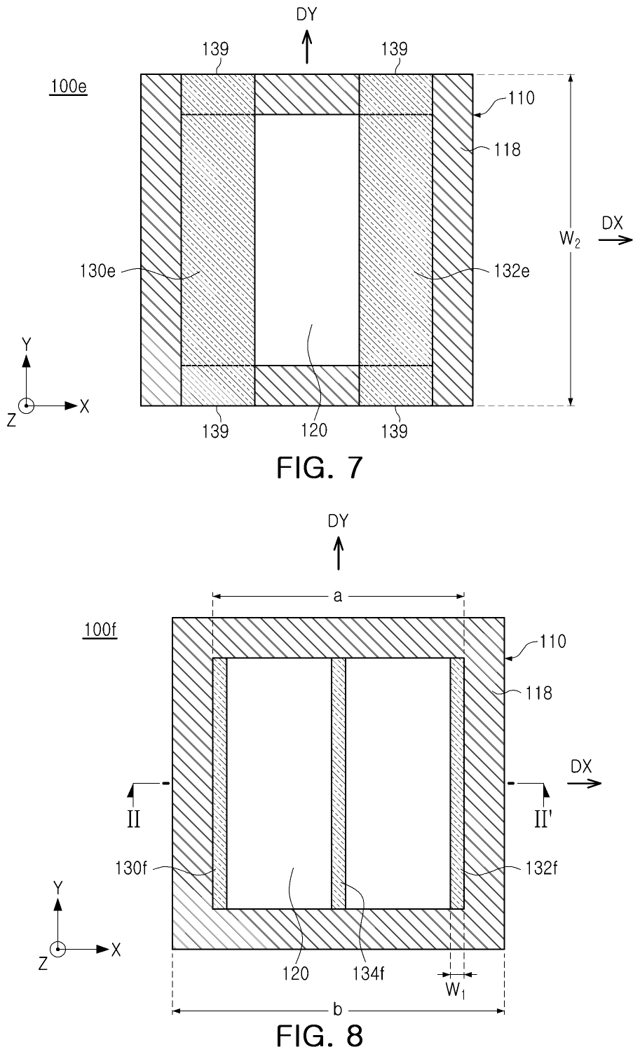

FIG. 8 is a fragmentary, plan view of a semiconductor package according to example embodiments. FIG. 9 is a vertical cross-sectional view taken along line II-II′ of the semiconductor package illustrated in FIG. 8.

Referring to FIGS. 8 and 9, a semiconductor package 100f may include a first spacer 130f, a second spacer 132f, and a third spacer 134f disposed on the semiconductor chip 120. The first spacer 130f and the second spacer 132f may be coplanar with side surfaces perpendicular to the X-direction DX of the semiconductor chip 120. The third spacer 134f may be disposed between the first spacer 130f and the second spacer 132f. The first spacer 130f, the second spacer 132f, and the third spacer 134f may have the same size. The semiconductor package 100f may further include a third adhesive layer 135 disposed between the third spacer 134f and the semiconductor chip 120.

The encapsulant 140 may include upper portions 141f disposed on the semiconductor chip 120. The upper portions 141f may be disposed between the first spacer 130f and the second spacer 132f and between the second spacer 132f and the third spacer 134f, respectively. In some embodiments, the encapsulant 140 (not shown in FIG. 8) of the semiconductor package 100f is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 8.

In an example embodiment, the width W₁ (FIG. 8) of the first spacer 130f, the second spacer 132f, and the third spacer 134f in the X-direction DX may each satisfy Equation 2 below.

$${W}_{1} = \frac{a}{3} - \frac{2 d ( b - a )}{3 c} \qquad [ Equation 2 ]$$

In this case, a is the width of the semiconductor chip 120 in the X-direction DX, b is the width of the substrate 110 in the X-direction DX, c is the thickness (in the vertical direction DZ) of the upper portion 141f of the encapsulant 140, and d is the thickness (in the vertical direction DZ) of the edge portions 142A, 142B of the encapsulant 140.

According to Equation 2, the cross-sectional area (in the X-Z plane) of each of the upper portions 141f of the encapsulant 140 may be substantially equal to the sum of the cross-sectional areas (in the X-Z plane) of the edge portions 142A, 142B of the encapsulant 140. For example, the first edge portion 142A and the second edge portion 142B may be spaced apart from each other in the X-direction DX with the semiconductor chip 120 interposed therebetween, and the sum of the cross-sectional areas (in the X-Z plane) of the first edge portion 142A and the second edge portion 142B may be equal to the cross-sectional area (in the X-Z plane) of each upper portion 141f of the encapsulant 140. The upper portions 141f may have the same size.

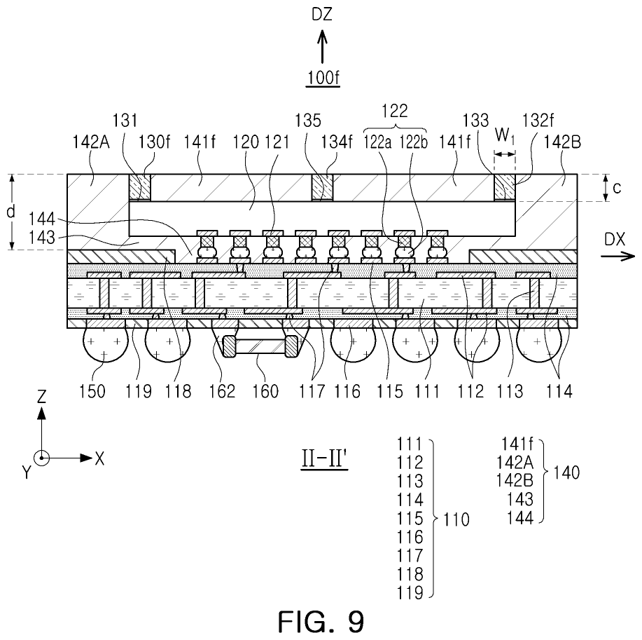

Referring to FIG. 10, a semiconductor package 100g may include a first spacer 130g, a second spacer 132g, and a third spacer 134g disposed on the semiconductor chip 120. In an example embodiment, the first spacer 130g, the second spacer 132g, and the third spacer 134g may extend in the Y-direction DY, and the length W₂ of the first spacer 130g, the second spacer 132g, and the third spacer 134g in the Y-direction may be greater than the length of the semiconductor chip 120 in the Y-direction. For example, the length W₂ may be substantially equal to the length of the substrate 110 in the Y-direction. Side surfaces 139 of the first spacer 130g, second spacer 132g, and third spacer 134g perpendicular to the Y-direction may be coplanar with the corresponding adjacent side surfaces of the substrate 110, and may be exposed without being covered by the encapsulant 140. In some embodiments, the encapsulant 140 (not shown in FIG. 10) of the semiconductor package 100g is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 10.

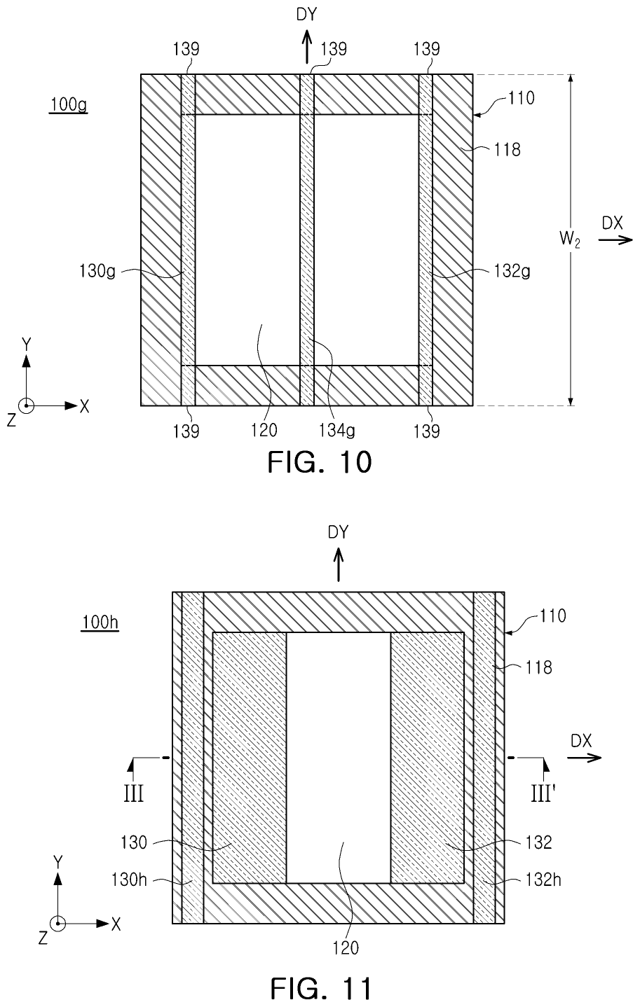

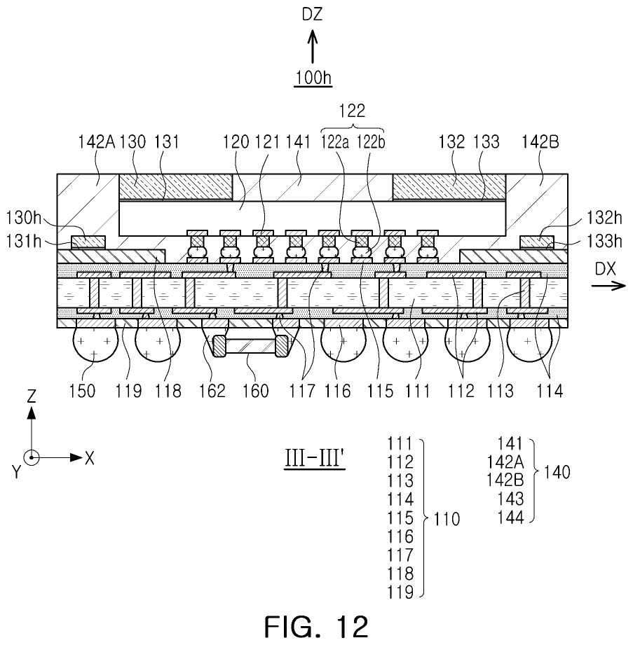

FIG. 11 is a fragmentary, plan view of a semiconductor package according to example embodiments. FIG. 12 is a vertical cross-sectional view taken along line III-III′ of the semiconductor package illustrated in FIG. 11.

Referring to FIGS. 11 and 12, a semiconductor package 100h may include a first spacer 130 and a second spacer 132 disposed on the semiconductor chip 120, and a first lower spacer 130h and a second lower spacer 132h disposed on the substrate 110. The first lower spacer 130h and the second lower spacer 132h may extend in the Y-direction DY along the substrate 110. The first lower spacer 130h and the second lower spacer 132h may be spaced apart from each other in the X-direction DX with the semiconductor chip 120 interposed therebetween. In an example embodiment, the length of the first lower spacer 130h and the second lower spacer 132h in the Y-direction DY may be greater than the length of the semiconductor chip 120 in the Y-direction DY. For example, the length may be equal to the length of the substrate 110 in the Y-direction DY. In an example embodiment, the semiconductor package 100h may further include a first lower adhesive layer 131h disposed between the substrate 110 and the first lower spacer 130h and a second lower adhesive layer 133h disposed between the substrate 110 and the second lower spacer 132h. The cross-sectional area of each edge portion 142A, 142B of the encapsulant 140 may be reduced by the area of the first lower spacer 130h and the lower adhesive layer 131h. In some embodiments, the encapsulant 140 (not shown in FIG. 11) of the semiconductor package 100h is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 11.

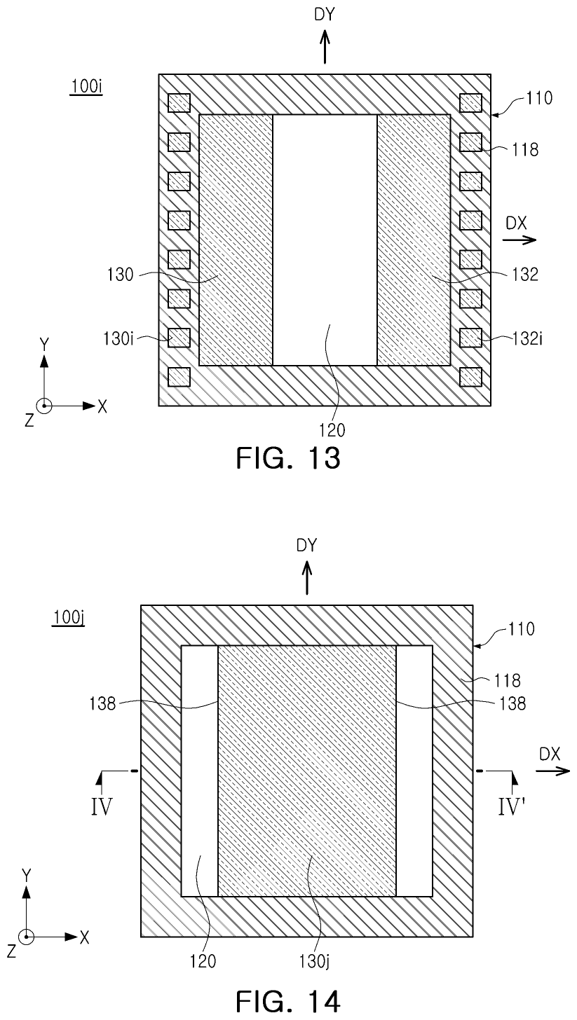

Referring to FIG. 13, a semiconductor package 100i may include a first spacer 130, a second spacer 132, and first lower spacers 130h and second lower spacers 132h disposed on the semiconductor chip 120. In an example embodiment, the first lower spacers 130h may be arranged to be spaced apart from each other in the Y-direction DY, and the second lower spacers 132h may be arranged to be spaced apart from each other in the Y-direction. In some embodiments, the encapsulant 140 (not shown in FIG. 13) of the semiconductor package 100i is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 13.

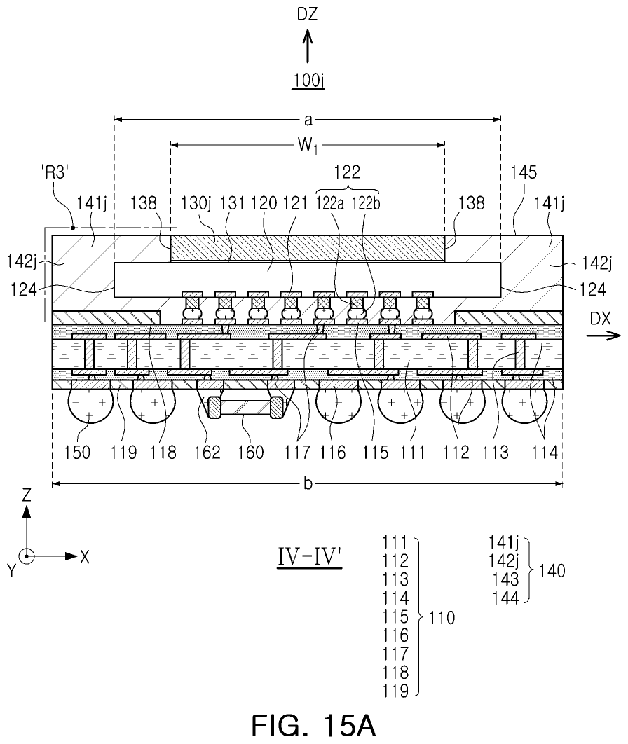

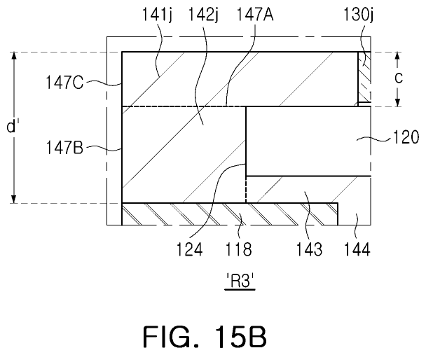

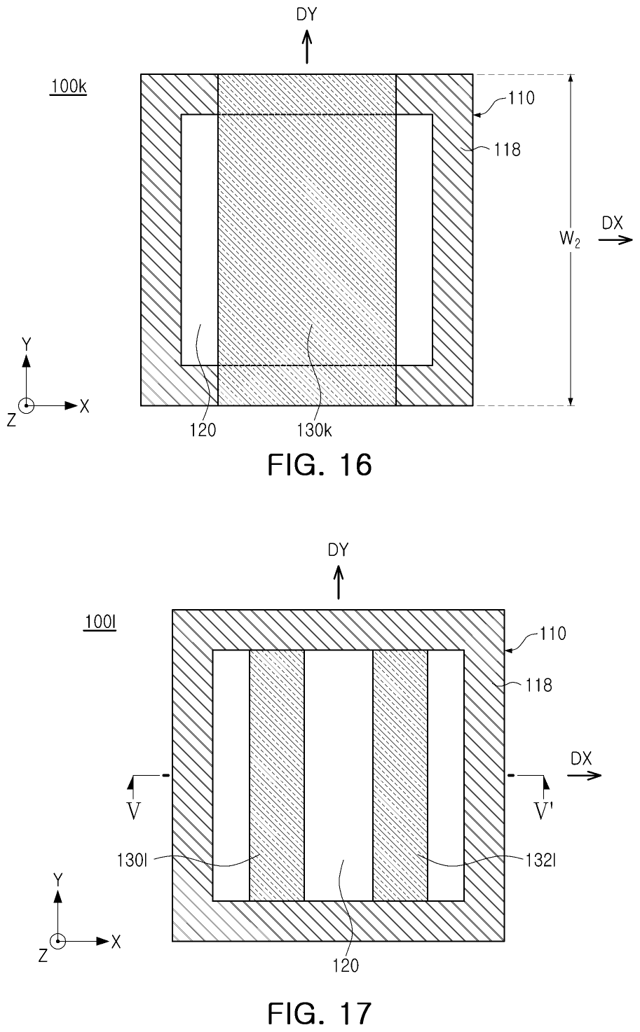

FIG. 14 is a fragmentary, plan view of a semiconductor package according to example embodiments. FIG. 15A is a vertical cross-sectional view along line IV-IV′ of the semiconductor package illustrated in FIG. 14. FIG. 15B is an enlarged view of a portion of the semiconductor package illustrated in FIG. 15A.

Referring to FIGS. 14 to 15B, a semiconductor package 100j may include a spacer 130j disposed on the semiconductor chip 120. In an example embodiment, the spacer 130j is not aligned with the side surfaces perpendicular to the X-direction DX of the semiconductor chip 120 and may be disposed offset. For example, the side surfaces 138 of the spacer 130j may not be coplanar with the corresponding side surfaces of the semiconductor chip 120 perpendicular to the X-direction DX.

The encapsulant 140 may include upper portions 141j, edge portions 142j, a first lower portion 143, and a second lower portion 144. The upper portion 141j of the encapsulant 140 is disposed on the semiconductor chip 120, and at least partially overlaps the semiconductor chip 120 in the vertical direction (Z-direction DZ). The edge portions 142j of the encapsulant 140 are disposed on the side surfaces 124 of the semiconductor chip 120, and at least partially overlap the semiconductor chip 120 in the X-direction DX. For example, in the embodiment of FIGS. 14 to 15B, the upper portions 141j overlap the spacer 130 in the X-direction DX and may be disposed on the semiconductor chip 120. The upper portions 141j may be in contact with the side surfaces 138 of the spacer 130j and the upper surface 145 of the upper portion 141j may be coplanar with the upper surface 137 of the spacer 130j.

The edge portions 142j are disposed on the upper protective layer 118 of the substrate 110 and may be disposed on both sides of the semiconductor chip 120. For example, the edge portions 142j may be spaced apart from each other in the X-direction DX with the semiconductor chip 120 interposed therebetween. The edge portions 142j may be in contact with the side surface 124 of the semiconductor chip 120 and may be spaced apart from the spacer 130j. The upper surfaces 147 (FIG. 15B) of the edge portions 142j may be in contact with the lower surfaces of the upper portions 141j, and the side surfaces 147B of the edge portions 142j may be coplanar with the side surfaces 147C of the upper portions 141j. In some embodiments, the encapsulant 140 (not shown in FIG. 14) of the semiconductor package 100j is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 14.

In an example embodiment, the width W1 (FIG. 15A) of the spacer 130j in the X-direction DX may satisfy Equation 3 below.

$${W}_{1} = 2 b - a - \frac{{d}^{′} ( b - a )}{c} \qquad [ Equation 3 ]$$

In this case, a is the width of the semiconductor chip 120 in the X-direction DX, b is the width of the substrate 110 in the X-direction DX, c is the thickness (in the vertical direction DZ) of the upper portion 141j of the encapsulant 140, and d′ is the height (in the vertical direction DZ) from the upper surface of the upper protective layer 118 of the substrate 110 to the upper surface of the upper portion 141j of the encapsulant 140. d′ is also equal to the sum of the thicknesses (in the vertical direction DZ) of the upper portion 141j and the edge portion 142j.

According to Equation 3, the cross-sectional area (in the X-Z plane) of each upper portion 141j of the encapsulant 140 may be substantially equal to the cross-sectional area (in the X-Z plane) of each edge portion 142j of the encapsulant 140. For example, the first upper portion 141j and the second upper portion 141j may be spaced apart from each other in the X-direction DX, and the first edge portion 142j and the second edge portion 142j may be spaced apart from each other in the X-direction DX. The first edge portion 142j and the second edge portion 142j may have the same cross-sectional area (in the X-Z plane) as the first upper portion 141j and the second upper portion 141j, respectively. In this case, the cross-sectional area may mean the area of the surface perpendicular to the Y-direction as seen from the X-Z plane.

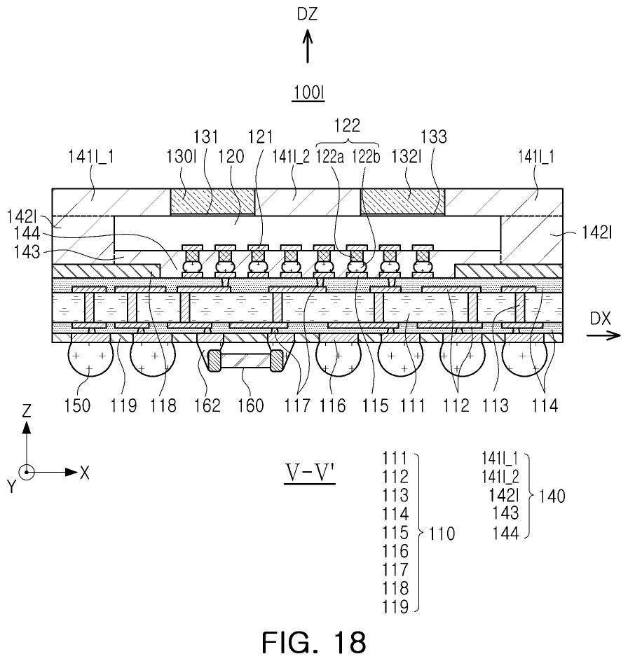

Referring to FIG. 16, the semiconductor package 100k may include a spacer 130k disposed on the semiconductor chip 120. In an example embodiment, the spacer 130k may extend in the Y-direction DY, and the length W₂ of the spacer 130k in the Y-direction may be greater than the length of the semiconductor chip 120 in the Y-direction. For example, the length W₂ may be substantially equal to the length of the substrate 110 in the Y-direction. Side surfaces perpendicular to the Y-direction of the spacer 130k may be coplanar with the side surface of the substrate 110 and may be exposed without being covered by the encapsulant 140. In some embodiments, the encapsulant 140 (not shown in FIG. 16) of the semiconductor package 100k is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 16.

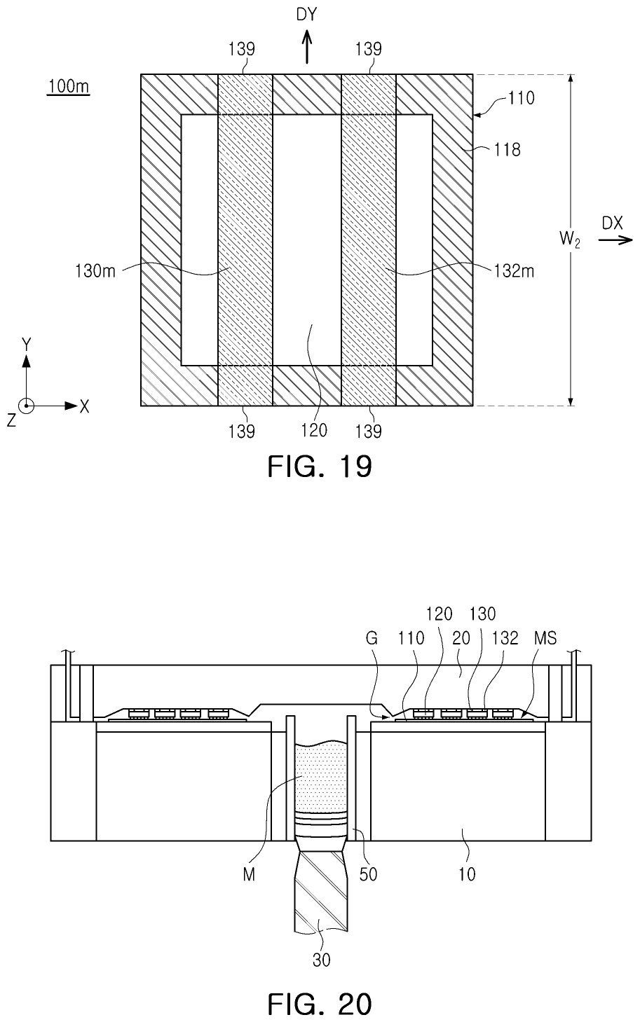

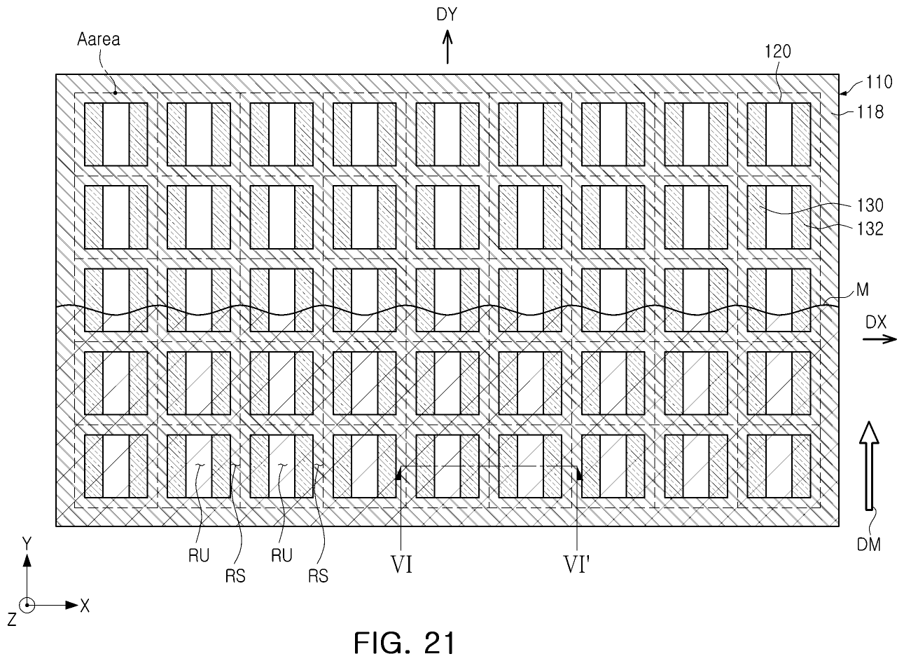

FIG. 17 is a fragmentary, plan view of a semiconductor package according to example embodiments. FIG. 18 is a vertical cross-sectional view along line V-V′ of the semiconductor package illustrated in FIG. 17.

Referring to FIGS. 17 and 18, the semiconductor package 100l may include a first spacer 130l and a second spacer 132l disposed on the semiconductor chip 120. In an example embodiment, the first spacer 130l and the second spacer 132l are not aligned with the side surfaces perpendicular to the X-direction DX of the semiconductor chip 120, and may be arranged offset.

The encapsulant 140 may include first upper portions 141l_1, second upper portions 141l_2, edge portions 142l, first lower portions 143, and second lower portions 144. The edge portions 142l are disposed on the upper protective layer 118 of the substrate 110 and may be disposed on both sides of the semiconductor chip 120. In the embodiments of FIGS. 17 and 18, the first upper portions 141_1 may overlap the spacer 130 in the X-direction DX and vertically overlap the edge portions 142l, and may be disposed on the semiconductor chip 120. The second upper portion 141l_2 may be disposed between the first spacer 130l and the second spacer 132l in the X-direction DX. The upper surfaces of the first upper portions 141_1 and the second upper portions 141l_2 may be coplanar with the upper surfaces of the first spacer 130l and the second spacer 132l. In some embodiments, the encapsulant 140 (not shown in FIG. 17) of the semiconductor package 100l is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 17.

In an example embodiment, the cross-sectional area (in the X-Z plane) of the first upper portion 141l_1 may be substantially equal to the cross-sectional area (in the X-Z plane) of the edge portion 142l. Additionally, the cross-sectional area (in the X-Z plane) of the first upper portion 141l_1 may be twice that of the second upper portion 141l_2. For example, the width of the first upper portion 141l_1 in the X-direction DX may be twice the width of the second upper portion 141l_2 in the X-direction DX.

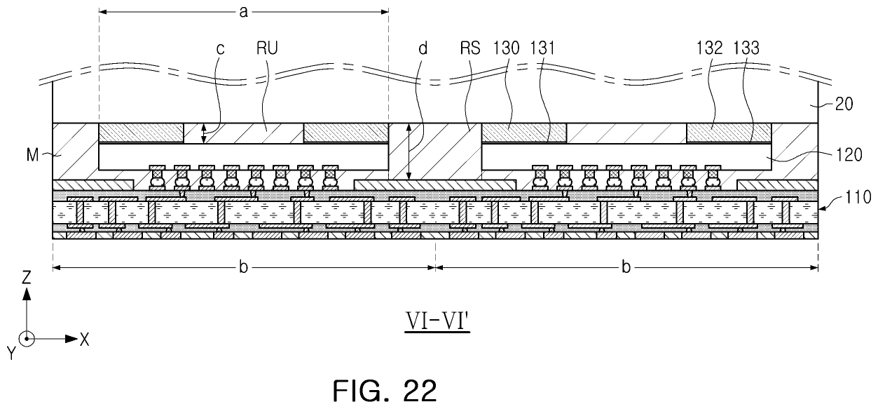

Referring to FIG. 19, the semiconductor package 100m may include a first spacer 130m and a second spacer 132m disposed on the semiconductor chip 120. In an example embodiment, the first spacer 130m and the second spacer 132m are not aligned with side surfaces perpendicular to the X-direction DX of the semiconductor chip 120, and may be arranged offset. In an example embodiment, the first spacer 130m and the second spacer 132m may extend in the Y-direction DY, and the length W₂ of the first spacer 130m and the second spacer 132m in the Y-direction may be greater than the length of the semiconductor chip 120 in the Y-direction. For example, the length W₂ may be substantially equal to the length of the substrate 110 in the Y-direction. The side surfaces 139 of the first spacer 130m and the second spacer 132m perpendicular to the Y-direction may be coplanar with the side surface of the substrate 110 and may be exposed without being covered by the encapsulant 140. In some embodiments, the encapsulant 140 (not shown in FIG. 19) of the semiconductor package 100m is a single, unitary element. In some embodiments, the encapsulant 140 covers (i.e., overlaps in the vertical direction DZ) all the portions of the upper surfaces of the upper protective layer 118 and the semiconductor chip 120 that are visible in the top plan view of FIG. 19.

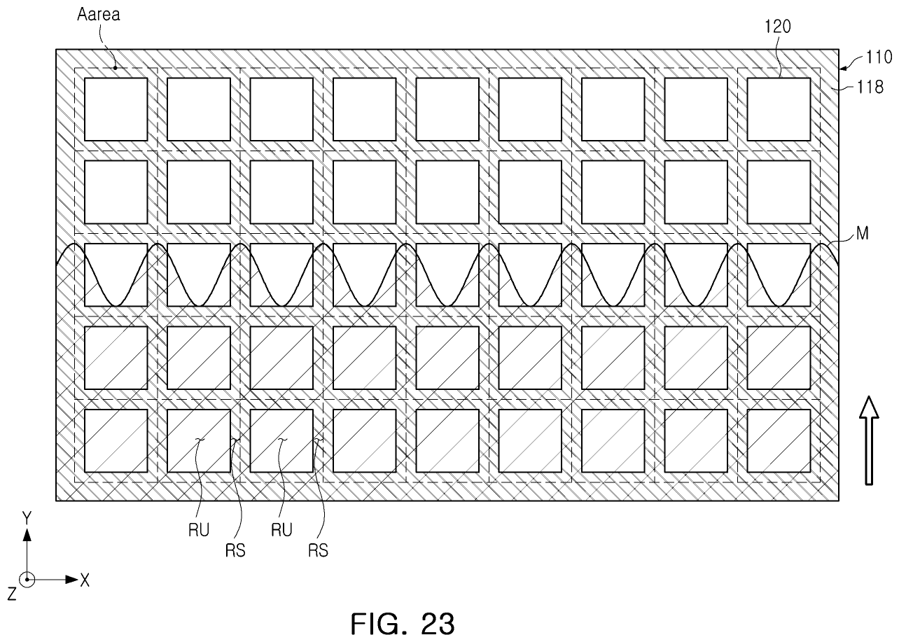

FIGS. 20 to 22 are diagrams illustrating a molding process according to example embodiments. FIG. 20 illustrates a vertical cross-sectional view of a mold for molding. FIG. 21 illustrates supplying molding material onto a substrate. FIG. 22 is a vertical cross-sectional view along line VI-VI′ in FIG. 21.

Referring to FIG. 20, the molding mold may include a lower mold 10 and an upper mold 20. A port 50 for supplying the molding material M may be disposed in the center of the lower mold 10. A molding space MS may be defined between the lower mold 10 and the upper mold 20. The molding space MS may be disposed on both sides of the port 50 and may extend in the Y-direction DY.

The molding material M may be supplied to the molding space MS through the gate G by the up-and-down reciprocating movement of the ram 30 disposed in the port 50. The molding process may be carried out simultaneously in the molding space MS disposed on both sides of the port 50. The molding material M may correspond to the encapsulant 140 of the semiconductor packages described above.

A substrate 110 may be placed in the molding space MS, and a semiconductor chip 120 and spacers 130 and 132 may be placed on the substrate 110. Spacers 130 and 132 may correspond to the spacers described with reference to FIGS. 1 to 19. For the purpose of explanation, the spacers 130, 132 illustrated in FIGS. 20-22 correspond to those of the semiconductor package 100 of FIGS. 1-2B. The molding material M supplied through the gate (G) may flow in the Y-direction DY and cover the substrate 110, the semiconductor chip 120, and the spacers 130 and 132.

Referring to FIGS. 21 and 22, active areas Aarea may be disposed on the substrate 110. Semiconductor chips 120 may be disposed in the active areas Aarea. Semiconductor chips 120 may be arranged in the X-direction DX and Y-direction DY. The first spacers 130 and second spacers 132 may be disposed on the semiconductor chips 120, respectively. The first spacers 130 and second spacers 132 may extend in the Y-direction DY.

Molding material M is provided within the molding space MS so that it may flow in the Y-direction (for example, in the direction indicated by the arrow DM). As illustrated in FIG. 21, in example embodiments, the first spacers 130 and the second spacers 132 may extend in the direction DM in which the molding material M flows.

In an example embodiment, a molding process may be performed while the first spacers 130 and the second spacers 132 are in contact with the upper mold 20. In an alternative example embodiment, the molding process may be performed while the first spacers 130 and the second spacers 132 are spaced apart from the upper mold 20. When the molding material M flows continuously in the Y-direction DY from the gate (G) into the molding space MS, if there is no friction, the smaller the cross-sectional area, the larger the flow rate may be. However, head loss may occur due to friction, and the flow rate of the molding material M may be reduced between the substrate 110 and the semiconductor chip 120. For example, the flow rate in the area corresponding to the first lower portion 143 and the second lower portion 144 of the encapsulant 140 illustrated in FIGS. 2A and 2B may be smaller than the flow rate in the area corresponding to the upper portion 141 and the edge portion 142. The area corresponding to the edge portion 142 is an area extending in the Y-direction DY between the semiconductor chips 120, and the area corresponding to the upper portion 141 is an area that vertically overlaps the semiconductor chips 120 and extends in the Y-direction DY.

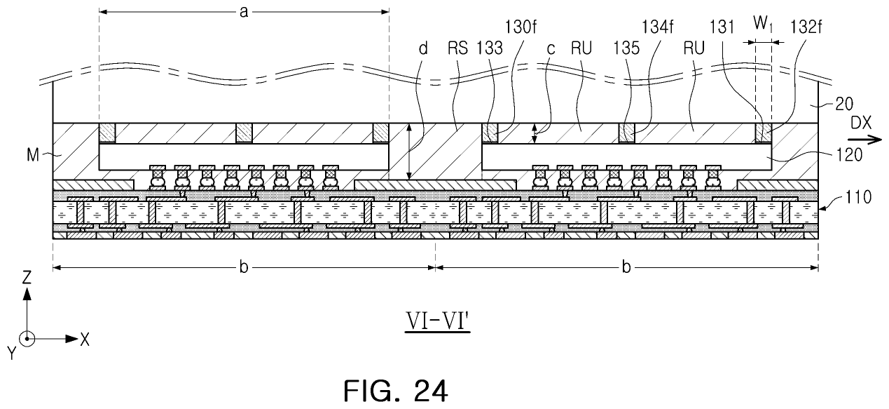

FIG. 23 is a plan view illustrating a molding process according to a comparative example.

Referring further to FIG. 23, in the comparative example, semiconductor chips 120 may be disposed on the substrate 110, and spacers may not be disposed on the semiconductor chips 120. As illustrated in FIG. 23, the molding material M may flow relatively quickly between the semiconductor chips 120 to first fill the area between the semiconductor chips 120 with the molding material M. For example, the flow rate of molding material M in the area corresponding to the edge portion 142 illustrated in FIG. 15B may be greater than the flow rate of molding material M in the area corresponding to the upper portion 141 (In the comparative example, unlike FIG. 15B, the spacer 130j is not disposed). Therefore, there is a risk of voids occurring within the encapsulant 140.

However, as illustrated in FIG. 22, according to example embodiments, since the cross-sectional area of the region RS extending in the Y-direction between the semiconductor chips 120 and the region RU on the semiconductor chips 120 are substantially the same, the flow rate of the molding material M in the region RS and the region RU may be equalized or the difference in flow rate may be reduced. Therefore, the occurrence of voids in the encapsulant 140 may be prevented or reduced.

With reference to FIG. 22, when the width of the semiconductor chip 120 in the X-direction DX is a, the width of the semiconductor package manufactured after the molding process in the X-direction DX is b, the height of the region RU is c, the height of the region RS is d, and the width of the first spacer 130 and the second spacer 132 in the X-direction is W₁; the cross-sectional area (in the X-Z plane) of the region RU may be (a−2W₁)·c, and the cross-sectional area (in the X-Z plane) of the region RS may be (b−a)·d. The width W₁ at which the cross-sectional areas of the region RS and the region RU are the same may satisfy Equation 1 described above.

Therefore, according to example embodiments, since the width W₁ of the first spacer 130 and the second spacer 132 in the X-direction satisfies Equation 1, the difference in the flow rate of the molding material M in the region RS and the region RU may be reduced, and the generation of voids in the encapsulant 140 may be prevented.

In an example embodiment, the area difference between the region RS and the region RU may be less than or equal to 10%. For example, the difference between the area of the region RS and the area of the region RU may be less than or equal to 10% of the larger of the area of the region RS and the area of the region RU. For example, in the embodiments of FIGS. 1 to 7, the difference in area between the area of the upper portion 141 of the encapsulant 140 and the area of the edge portions 142 may be less than or equal to 10%.

As illustrated in FIGS. 3 to 6, when the width of the first spacer 130 and the second spacer 132 in the X-direction changes in the Y-direction, the flow of molding material M in the region RU may be controlled. As illustrated in FIGS. 11 to 13, when the first lower spacers 130h and 130i and the second lower spacers 132h and 132i are disposed on the substrate 110, the flow of molding material M in the region RS may be controlled.

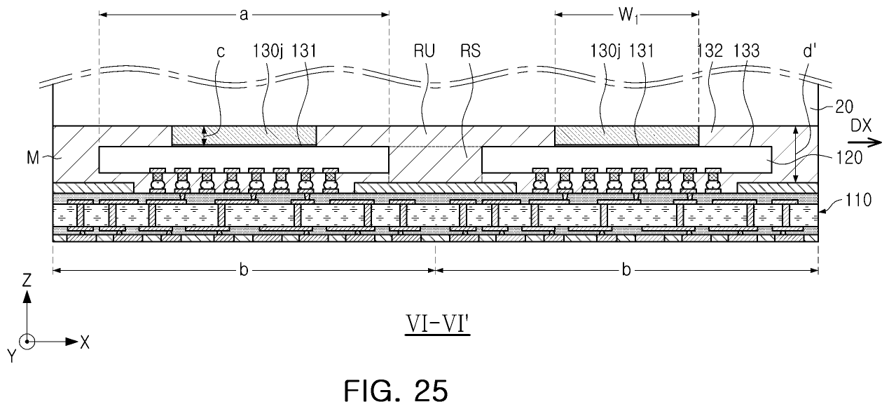

FIGS. 24 and 25 are diagrams illustrating a molding process according to example embodiments.

FIG. 24 is a diagram for explaining a molding process for forming the encapsulant 140 illustrated in FIG. 9. Referring to FIG. 24, a first spacer 130f, a second spacer 132f, and a third spacer 134f may be disposed on the semiconductor chip 120 as described herein with reference to FIGS. 8 and 9, for example.

The regions RU on the semiconductor chips 120 may be disposed between the first spacer 130f and the second spacer 132f and between the second spacer 132f and the third spacer 134f. Similar to what was described with reference to FIG. 22, when the region RU and the region RS are substantially the same, the flow rate of the molding material M in the region RS and the region RU may be equalized or the difference in flow rate may be reduced.

When the width of the semiconductor chip 120 in the X-direction DX is a, the width of the semiconductor package manufactured after the molding process in the X-direction DX is b, the height of the region RU is c, the height of the region RS is d, and the width of the first spacer 130f, the second spacer 132f and the third spacer 134f in the X-direction DX is W₁; the cross-sectional area (in the X-Z plane) of the region RU may be

$$\frac{a - 3 {W}_{1}}{2} .$$

c, and the cross-sectional area (in the X-Z plane) of the region RS may be (b−a)·d. The width W₁ at which the cross-sectional area of the region RU is the same may satisfy Equation 2 described above.

In generalizing the embodiments of FIGS. 2A and 24, in an example embodiment, when n spacers are disposed on each semiconductor chip 120 (where n is an integer greater than 1), the X-direction width W₁ of spacers spaced at regular intervals in the X-direction and having the same size may satisfy the following equation 4.

$${W}_{1} = \frac{a}{n} - \frac{d ( b - a ) ( n - 1 )}{c n} \qquad [ Equation 4 ]$$

At this time, two of the spacers may be coplanar with the side perpendicular to the X-direction of the semiconductor chip 120.

FIG. 25 is a diagram for explaining a molding process for forming the encapsulant 140 illustrated in FIG. 15A. Referring to FIG. 25, a spacer 130j may be disposed on the semiconductor chip 120 as described herein with reference to FIGS. 14-15B, for example. The regions RU on the semiconductor chips 120 may be disposed between adjacent spacers 130j and may be disposed on the semiconductor chips 120. The regions RS may be disposed under the regions RU and between the semiconductor chips 120. Similar to what was described with reference to FIG. 22, when the region RU and the region RS are substantially the same, the flow rate of the molding material M in the region RS and the region RU may be equalized or the difference in flow rate may be reduced.

When the width of the semiconductor chip 120 in the X-direction DX is a, the width of the semiconductor package manufactured after the molding process in the X-direction DX is b, the height of the region RU is c, the sum of the heights of the region RU and the region RS is d′, and the width of the spacer 130j in the X-direction DX is W₁; the cross-sectional area of the region RU may be

$$\frac{( b - {W}_{1} ) \cdot c}{2} ,$$

and the cross-sectional area of the region RS may be

$$\frac{( b - a )}{2} \cdot ( {d}^{′} - c ) .$$

The width W₁ at which the cross-sectional area of the region RU is the same may satisfy Equation 3 described above.

As set forth above, according to example embodiments, a spacer may be disposed on a semiconductor chip. During a molding process to manufacture semiconductor packages, a molding material may be flowed onto the semiconductor chip to form an encapsulant. The spacer, the semiconductor chip and the encapsulant together form components of the semiconductor package. During manufacture, the spacer may regulate the flow rate of the molding material in the areas between adjacent semiconductor chips and the flow rate of the molding material in the areas on the semiconductor chips. The cross-sectional areas of the region corresponding to an upper portion of the encapsulant and the region corresponding to an edge portion of the encapsulant may be substantially equal to each other during the molding process. Accordingly, the flow rate in the areas between semiconductor chips is substantially equal to the flow rate in the area on the semiconductor chips, thereby preventing or reducing occurrence of voids within the encapsulant of each semiconductor package. Additionally, the upper surface of the spacer is exposed by the encapsulant, and since the spacer includes material with higher thermal conductivity than the encapsulant, the spacer may effectively radiate heat generated from the semiconductor chip externally to dissipate heat from the semiconductor package.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a semiconductor chip on a substrate;
a first spacer on the semiconductor chip and extending in a first horizontal direction;
a second spacer on the semiconductor chip, extending in the first horizontal direction, and spaced apart from the first spacer in a second horizontal direction, wherein the second horizontal direction intersects the first horizontal direction; and
an encapsulant at least partially covering the substrate, the semiconductor chip, the first spacer, and the second spacer,
wherein:
the encapsulant includes an upper portion, a first edge portion and a second edge portion,
the upper portion of the encapsulant is between the first spacer and the second spacer,
the first edge portion and the second edge portion of the encapsulant overlap the semiconductor chip in the second horizontal direction and are spaced apart from each other in the second horizontal direction, with the semiconductor chip interposed between the first edge portion and the second edge portion of the encapsulant,
an upper surface of the first spacer is coplanar with an upper surface of the upper portion of the encapsulant, and
a cross-sectional area of the upper portion of the encapsulant is substantially equal to a sum of a cross-sectional area of the first edge portion of the encapsulant and a cross-sectional area of the second edge portion of the encapsulant.

2. The semiconductor package of claim 1, wherein the first spacer and the second spacer each include a material having thermal conductivity higher than thermal conductivity of the encapsulant.

3. The semiconductor package of claim 2, wherein the first spacer and the second spacer each include silicon.

4. The semiconductor package of claim 1, wherein the upper surface of the first spacer and an upper surface of the second spacer are exposed by the encapsulant.

5. The semiconductor package of claim 1, further comprising a first adhesive layer between the semiconductor chip and the first spacer and a second adhesive layer between the semiconductor chip and the second spacer.

6. The semiconductor package of claim 1, wherein a length of the first spacer in the first horizontal direction is substantially equal to a length of the semiconductor chip in the first horizontal direction.

7. The semiconductor package of claim 1, wherein an upper surface of the first edge portion and an upper surface of the second edge portion of the encapsulant are coplanar with an upper surface of the first spacer.

8. The semiconductor package of claim 1, wherein a width of the first spacer in the second horizontal direction varies along the first horizontal direction.

9. The semiconductor package of claim 8, wherein a width of the upper portion of the encapsulant in the second horizontal direction is constant in the first horizontal direction.

10. The semiconductor package of claim 1, wherein a length of the first spacer in the first horizontal direction is greater than a length of the semiconductor chip in the first horizontal direction.

11. The semiconductor package of claim 10, wherein the length of the first spacer in the first horizontal direction is substantially equal to a length of the substrate in the first horizontal direction.

12. The semiconductor package of claim 10, wherein a side surface of the first spacer is exposed by the encapsulant.

13. The semiconductor package of claim 1, wherein:
the upper portion of the encapsulant is a first upper portion of the encapsulant;
the semiconductor package further includes a third spacer between the first spacer and the second spacer,
the semiconductor package further includes a second upper portion of the encapsulant,
the first upper portion of the encapsulant is disposed between the first spacer and the second spacer, and the second upper portion of the encapsulant is disposed between the second spacer and the third spacer, and
a cross-sectional area of the first upper portion of the encapsulant and a cross-sectional area of the second upper portion of the encapsulant are each substantially equal to a sum of the cross-sectional area of the first edge portion and the cross-sectional area of the second edge portion.

14. The semiconductor package of claim 1, further comprising a first lower spacer and a second lower spacer on the substrate and spaced apart from each other in the second horizontal direction, with the semiconductor chip interposed between the first lower spacer and the second lower spacer.

15. The semiconductor package of claim 14, including a plurality of first lower spacers spaced apart from each other in the first horizontal direction, and a plurality of second lower spacers spaced apart from each other in the first horizontal direction.

16. The semiconductor package of claim 1, wherein a width of the first spacer in the second horizontal direction is substantially equal to a width of the second spacer in the second horizontal direction, and
a width W₁ of the first spacer in the second horizontal direction satisfies Equation 1:
$${W}_{1} = \frac{a}{2} - \frac{d ( b - a )}{2 c} ,$$
where a is a width of the semiconductor chip in the second horizontal direction, b is a width of the substrate in the second horizontal direction, c is a thickness of the upper portion of the encapsulant in a vertical direction perpendicular to the first and second horizontal directions, and d is a thickness of the first edge portion of the encapsulant in the vertical direction.

17. A semiconductor package comprising:
a semiconductor chip on a substrate;
a plurality of spacers on the semiconductor chip, extending in a first horizontal direction, and spaced apart from each other in a second horizontal direction, wherein the second horizontal direction intersects the first horizontal direction; and
an encapsulant at least partially covering the substrate, the semiconductor chip, and the plurality of spacers,
wherein:
the encapsulant includes at least one upper portion, a first edge portion and a second edge portion,
the at least one upper portion of the encapsulant is or are between the plurality of spacers,
the first edge portion and the second edge portion of the encapsulant overlap the semiconductor chip in the second horizontal direction and are spaced apart from each other in the second horizontal direction with the semiconductor chip interposed between the first edge portion and the second edge portion of the encapsulant,
upper surfaces of the plurality of spacers are coplanar with an upper surface or upper surfaces of the at least one upper portion of the encapsulant, and
a cross-sectional area of each of the at least one upper portion of the encapsulant is substantially equal to a sum of a cross-sectional area of the first edge portion of the encapsulant and a cross-sectional area of the second edge portion of the encapsulant.

18. The semiconductor package of claim 17, wherein the plurality of spacers have the same size and are disposed at regular intervals in the second horizontal direction, and
a width W₁ of each of the plurality of spacers in the second horizontal direction satisfies Equation 2:
$${W}_{1} = \frac{a}{n} - \frac{d ( b - a ) ( n - 1 )}{c n} ,$$
where a is a width of the semiconductor chip in the second horizontal direction, b is a width of the substrate in the second horizontal direction, c is a thickness of the at least one upper portion of the encapsulant in a vertical direction perpendicular to the first and second horizontal directions, d is a thickness of the first edge portion of the encapsulant in the vertical direction, and n is an integer greater than 1.

19. The semiconductor package of claim 17, wherein the plurality of spacers include a first spacer and a second spacer,
wherein the first spacer and the second spacer are coplanar with side surfaces of the semiconductor chip in the second horizontal direction.

20. A semiconductor package comprising:
a substrate including an upper pad and an upper protective layer, wherein the upper pad is exposed by the upper protective layer;
a semiconductor chip on the substrate;
a bump structure between the substrate and the semiconductor chip and electrically connected to the upper pad;
a first spacer on the semiconductor chip and extending in a first horizontal direction;
a second spacer on the semiconductor chip, extending in the first horizontal direction, and spaced apart from the first spacer in a second horizontal direction, wherein the second horizontal direction intersects the first horizontal direction;
a first adhesive layer between the semiconductor chip and the first spacer;
a second adhesive layer between the semiconductor chip and the second spacer; and
an encapsulant at least partially covering the substrate, the semiconductor chip, the bump structure, the first spacer, and the second spacer,
wherein:
the encapsulant includes an upper portion, a first edge portion and a second edge portion,
the upper portion of the encapsulant is between the first spacer and the second spacer,
the first edge portion and the second edge portion of the encapsulant overlap the upper protective layer in a vertical direction perpendicular to the first and second horizontal directions and are spaced apart from each other in the second horizontal direction with the semiconductor chip interposed between the first edge portion and the second edge portion,
an upper surface of the first spacer is coplanar with an upper surface of the upper portion of the encapsulant, and
a cross-sectional area of the upper portion of the encapsulant is substantially equal to a sum of a cross-sectional area of the first edge portion of the encapsulant and a cross-sectional area of the second edge portion of the encapsulant.
